(19) United States
(12) Patent Application Publication
(10) Pub. No.: US 2006/0030136 A1
(43) Pub. Date: Feb. 9, 2006

(54) METHOD OF FABRICATING A GATE OXIDE LAYER

(76) Inventor: Tung-Po Chen, Taichung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/905,086

(22) Filed: Dec. 14, 2004

(30) Foreign Application Priority Data
Aug. 3, 2004 (TW) 93123207

(51) Int. Cl. H01L 21/469

(52) U.S. Cl. 438/585; 438/745; 438/770; 438/766

(57) ABSTRACT

A method of fabrication a gate oxide layer includes providing a substrate and an isolation structure on the substrate so as to isolate an active region. A spacer is formed on the sidewalls of the isolation structure. Using the isolation structure having the spacer as a mask, a dopant is implanted into the substrate for reducing the oxidation rate of the substrate. Thereafter, the spacer and a portion of the isolation structure are removed and an oxidation process is performed to form a gate oxide layer with a uniform thickness over the substrate.

### CROSS-REFERENCE TO RELATED APPLICATION

This application claims the priority benefit of Taiwan application serial No. 93123207, filed Aug. 03, 2004.

### BACKGROUND OF THE INVENTION

1. Field of the Invention

The present invention relates to a method of fabricating a semiconductor device. More particularly, the present invention relates to a method of fabricating a gate oxide layer.

2. Description of Related Art

As the integration of devices continues to increase, the isolation between devices becomes an important issue. To prevent a short circuit between neighboring transistors, an isolation structure is disposed therebetween. A common device isolation technique is the LOCOS technique. The LOCOS technique, however, encompasses many drawbacks, which include the generation of stress and the formation of bird's beak near the peripheral of the isolation structure. As a result, a LOCOS isolation structure can not be used for an effective isolation of miniature devices.

Accordingly, other device isolation techniques are gradually being developed. For example, the shallow trench isolation (SOI) technique is applied to enhance the isolation of MOS transistors.

In the conventional fabrication process for a shallow trench isolation, a pad oxide layer and a silicon nitride mask layer are sequentially formed on a substrate. A photolithography process is performed to define a region for the formation a trench, followed by dry etching the silicon nitride mask layer, the pad oxide layer and the substrate sequentially to form a trench in the substrate. The area surrounded by the trench is the active region, on which various active devices are formed in the subsequent processes.

Thereafter, a liner oxide layer is formed on the surface of the trench by a thermal oxidation process. Chemical vapor deposition is performed under normal pressure to deposit a silicon oxide layer in the trench and on the silicon nitride mask layer. Chemical mechanical polishing is then conducted to remove the silicon oxide layer above the silicon nitride layer to form the shallow trench isolation structure in the trench. Hot phosphoric acid solution and hydrofluoric acid solution to remove the silicon nitride mask layer and the pad oxide, respectively.

However, during the fabrication process of the shallow trench isolation structure, removing the pad oxide layer and the mask layer with isotropic etching will lead to the formation of dents at the top edge corner of the shallow trench isolation structure. These dents will induce sub-threshold leakage current in integrated circuit, and this phenomenon is known as the kink effect. The abnormal kink effect lowers the quality of devices and yields of the process. Further, in the subsequent formation of the gate oxide layer, the oxidation rate is greatly affected by the dents at the top edge corner of the shallow trench isolation structure. Consequently, the gate oxide layer formed at the top edge corner of the shallow trench isolation structure is thinner than the gate oxide layer formed at the active region, and a gate oxide layer with a non-uniformed thickness is resulted.

Moreover, when the gate oxide layer is used as the tunneling oxide layer of a memory device, the demand for a good quality oxide layer is high. A thinning of a gate oxide layer will lower the reliability of the memory device.

### SUMMARY OF THE INVENTION

The present invention provides a method for fabricating a gate oxide layer, wherein dopants are implanted into the substrate to lower the oxidation rate of the gate oxide layer that is being formed on the substrate. A thinning of the gate oxide layer is thereby prevented to increase the reliability of the device.

The present invention further provides a fabrication method for a gate oxide layer, wherein the thickness of the gate oxide layer remains uniform at the border between the substrate and the shallow trench isolation structure to prevent a generation of leakage current in the device.

The present invention provides a method of fabricating a gate oxide layer. The substrate also includes a shallow trench isolation structure for isolating the active region, and a spacer is formed on the sidewall of the isolation structure. Using the isolation structure with the spacer as a mask, dopants are implanted into the substrate to lower the oxidation rate of the substrate. The spacer is subsequently removed, followed by removing a portion of the isolation structure to expose the substrate surface. An oxidation process is then performed to form a gate oxide layer on the substrate.

In accordance to an embodiment of the invention, the present invention provides an isolation structure with a spacer as a mask for the implantation of the nitrogen ions into the substrate in order to lower the growth grate of silicon oxide. As a result, the oxidation rate at the top edge corner of the trench and the oxidation rate at the central region of the substrate are substantially the same. A gate oxide layer with a uniform thickness is thus formed on the substrate to prevent the generation of leakage current in a device and to improve the reliability of the device.

The present invention further provides a method of fabricating a gate oxide layer. A substrate is provided, wherein the substrate includes a trench and a mask layer covering an active region surrounded by the trench. An insulation layer is formed on the substrate filling the trench but exposing the mask layer. A portion of the mask layer is removed to form a spacer on the sidewall of the insulation layer and expose a portion of substrate surface at the active region. Dopants are then implanted into the exposed portion of the substrate at the active region such that the oxidation rate of the substrate at the active region is substantially the same as the oxidation rate of the substrate at the top edge corner of the trench. Thereafter, the spacer is removed, followed by removing a portion of the insulation layer to expose the substrate near the top corner of the trench. An oxidation process is further performed on the substrate to form a gate oxide layer.

In accordance to another embodiment of the invention, during the process in removing a portion of the mask layer, spacer is directly formed on the sidewall of the insulation layer to simplify the fabrication process and to reduce the production cost.

Further, the insulation layer (isolation structure) with the spacer on the sidewall can serve as a mask for the implantation of the nitrogen ions in order to lower the growth rate of silicon oxide. The oxidation rate at the top edge corner of the trench is thus substantially the same as the oxidation rate at the central part of the active region. A gate oxide layer with a uniform thickness is thus formed to prevent a thinning of the gate oxide layer and to improve the reliability of the device.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention

FIGS. 1A to 1G are schematic, cross-sectional view diagrams of a part of a semiconductor device for illustrating the fabrication process of a gate oxide layer according to one embodiment of the present invention.

FIGS. 2A to 2B are schematic, cross-sectional view diagrams of a part of a semiconductor device for illustrating the fabrication process of a gate oxide layer according to another embodiment of the present invention.

### DESCRIPTION OF THE PREFERRED EMBODIMENTS

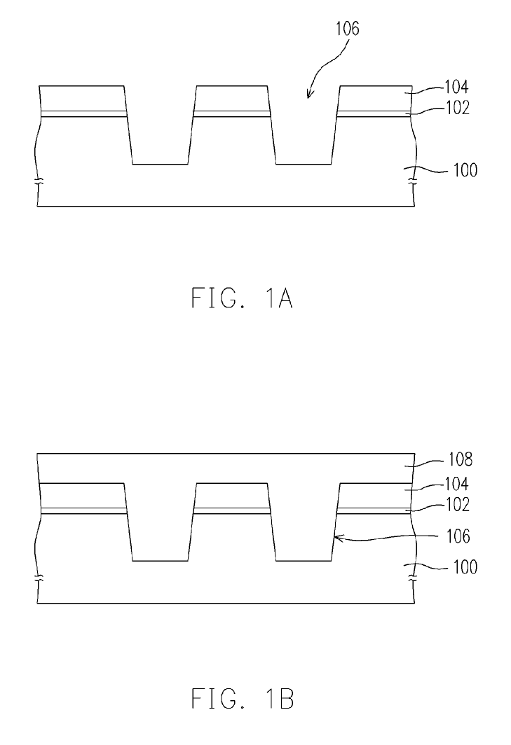

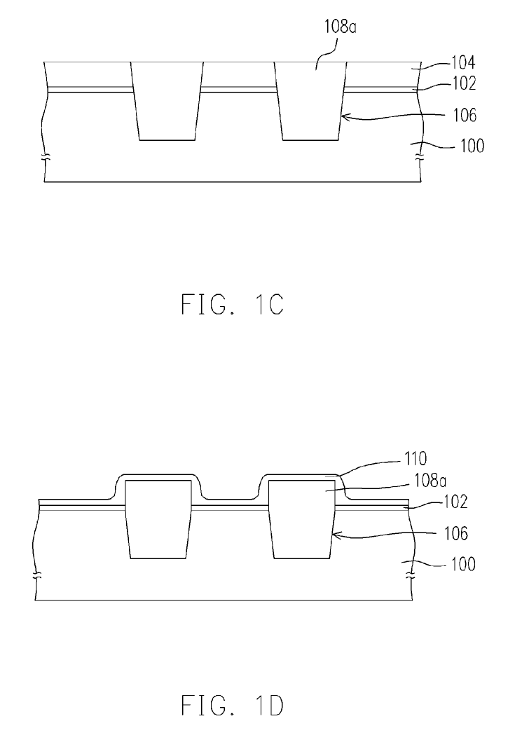

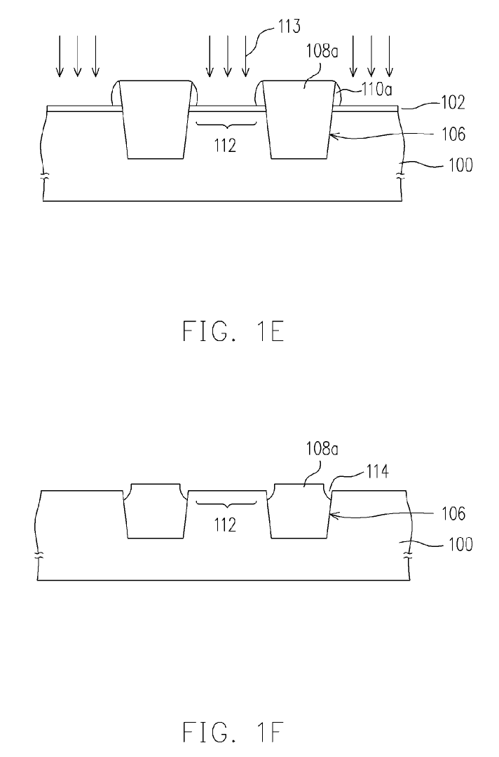

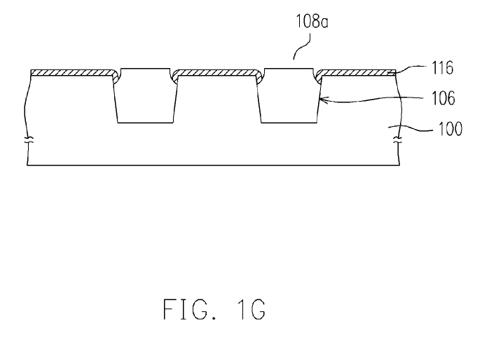

FIGS. 1A to 1G are schematic, cross-sectional view diagrams of a part of a semiconductor device for illustrating the fabrication process for a gate oxide layer according to one embodiment of the present invention.

Referring to FIG. 1A, a substrate 100, for example, a silicon substrate, is provided. A pad oxide layer 102 is formed on the substrate 100. A material used in forming the pad oxide layer 102 is, but not limited to, silicon oxide. The pad oxide layer 102 is formed by thermal oxidation, for example. The pad oxide layer 102 serves to protect the substrate 100 underneath from being damaged due to stress generated from the subsequently formed mask layer (silicon nitride layer).

A mask layer 104 is then formed on the pad oxide layer 102. The mask layer 104 is formed with, but not limit to, a silicon nitride material. The mask layer 104 is formed by chemical vapor deposition (CVD), for example. A photoresist layer (not shown) is further formed to cover the substrate 100. After the exposure and development processes are performed on the photoresist layer, a patterned photoresist layer is resulted. Using the patterned photoresist layer as a mask, an etching process is performed to pattern the mask layer 104 and the pad oxide layer 102, followed by removing the patterned photoresist layer. Further using the mask layer 104 and the pad oxide layer 102 as masks, an etching process is performed. The etching process can be a dry etching process to form a trench 106 in the substrate 100.

Referring to FIG. 1B, an insulation material 108 is formed on the substrate 100. The insulation material 108 is a silicon oxide material, for example. The insulation material 108 is formed by, for example, chemical vapor deposition using tetra ethyl ortho silicate (TEOS) and ozone (O₃) as a reaction gas source.

Continue to FIG. 1C, a portion of the insulation material layer 108 is removed to expose the mask layer 104 to form the insulation layer 108a (isolation structure) that fills the trench 106. Removing the portion of the insulation layer 108 includes but not limited to performing chemical mechanical polishing to the insulation material layer 108 until the surface of the mask layer 104 is exposed.

Referring to FIG. 1D, the mask layer 104 is then removed, wherein the mask layer 104 is removed by but not limited to wet etching using hot phosphoric acid as an etchant. Thereafter, a material layer 110 is formed on the substrate 100. The material layer 110 includes material that has an etching selectivity different from that of the material used for the insulation layer (isolation structure) 108a. The material layer 110 is formed by chemical vapor deposition, for example.

Referring to FIG. 1E, a portion of the material layer 110 is removed to form a spacer 110a on a sidewall of the insulation layer 108a (isolation structure), wherein removing the portion of the material layer 110 includes but not limited to performing anisotropic etching. A material used in fabricating the spacer 110a includes a silicon nitride material layer formed chemically vapor deposition, for example. Thereafter, the insulation layer 108a having a spacer 110a is used as a mask for an implantation process 113 to implant dopants into the substrate 100 in order to form a doped region 112 (active region) in the substrate 100. The oxidation rate at the doped region 112 is lower than that at other undoped region. Dopants that can slow down the oxidation rate of the substrate 100 include, for example, nitrogen ions, wherein the dopant concentration is about 5×10¹¹/cm² to about 1×10¹⁵/cm².

Referring to FIG. 1F, the spacer 110a is then removed until the surface of the pad oxide layer 102 is exposed. The spacer 110a is removed by methods including but not limited to wet etching using hot phosphoric acid solution as an etchant. The pad oxide layer 102 and a portion of the insulation layer 108a (isolation structure) are removed to expose the surface of the substrate 100 and the substrate near the top edge corner 114 of the trench. The pad oxide layer 102 and the portion of the insulation layer 108a are removed by wet etching, for example, using hydrofluoric acid as an etchant.

Referring to FIG. 1G, a gate oxide layer 116 is then formed on the substrate near the top edge corner 114 of the trench and the substrate surface 100 at the doped region 112. The gate oxide layer 116 is a silicon oxide material, for example, formed by thermal oxidation.

In the above embodiment of the present invention, nitrogen ions are implanted into the substrate 100 (active region) to lower the growth rate of silicon oxide. Therefore, the oxidation rate at the top edge corner of the trench is substantially equal to the oxidation rate at the central part of the active region. Consequentially, the gate oxide layer formed on the substrate 100 is more uniform in thickness. The reliability of the devices can thereby increased.

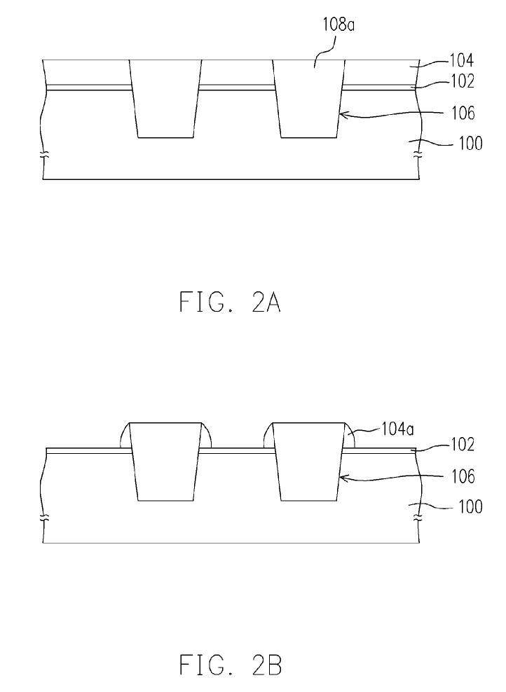

In another embodiment of the invention for fabricating a gate oxide layer, the spacer can form with the residual of the mask layer remaining on the sidewall of the insulation layer during the removal step of the mask layer. FIG. 2A to 2B are schematic cross-sectional view diagrams of a part of a semiconductor device for illustrating the fabrication process of a gate oxide layer according to another embodiment of the present invention. Referring to FIG. 2A, the structure shown in FIG. 2A, for example, is fabricated following the process steps as shown in FIGS. 1A-1C, wherein a substrate 100 having a trench 106 is provided. The substrate 100 also includes a pad oxide layer 102 and a mask layer 104 covering the portion of the substrate 100 surrounded by the trench 106. The trench 106 is filled with an insulation layer (isolation structure) 108a. In this embodiment, as shown in FIG. 2B, the spacer 104a is formed by performing an anisotropic etching on the mask layer 104, for example, dry etching, to remove a portion of the mask layer 104. The residual of the mask layer remaining on the sidewall of the insulation layer then serves as the spacer 104a. This method in forming the spacer directly can simplify the fabrication process and curtail the production cost.

The present invention provides a fabrication method for a gate oxide layer. Since no dopants are implanted to the substrate at the top edge corner of the trench, while dopants implanted at the doped region 112 slow down the oxidation rate at the doped region 112, the oxidation rates at the substrate near the top edge corner 114 of the trench and at the surface substrate of the doped region are more consistent. As a result, the thickness of the gate oxide layer formed on the substrate at the central region of the substrate and near the top edge corner of the trench is uniform. The reliability of the device is thereby enhanced.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A method for fabricating a gate oxide layer, the method comprising:
providing a substrate, the substrate comprising an isolation structure to isolate an active region, a spacer formed on a sidewall of the isolation structure and a pad oxide layer formed on the active region;
implanting dopants into the substrate using the isolation structure with the spacer as masks to lower the oxidation rate of the substrate;
removing the spacer;
removing the pad oxide layer and a portion of the isolation structure to expose a surface of the substrate; and
performing an oxidation process to form a gate oxide layer on the substrate.

2. The method of claim 1, the step of implanting the dopants into the substrate comprises performing an ion implantation process.

3. The method of claim 2, wherein the dopants comprises nitrogen ions.

4. The method of claim 2, wherein a concentration of the dopants is about 5×10¹¹/cm² to 1×10¹⁵/cm².

5. The method of claim 1, wherein the step of forming the spacer on the sidewall of the isolation structure comprises:
forming a material layer on the substrate; and
removing a portion of the material layer by an anisotropic etching method.

6. The method of claim 1, wherein a material used in forming the spacer comprises silicon nitride.

7. The method of claim 1, wherein the step of removing the spacer comprises performing a wet etching process.

8. The method of claim 7, wherein performing the wet etching process comprises using a hot phosphoric acid solution as an etchant.

9. The method of claim 1, wherein the step of removing the pad oxide layer and the portion of the isolation structure to expose the surface of the substrate comprises performing a wet etching process.

10. The method of claim 1, wherein the step of forming the gate oxide layer comprises conducting a thermal oxidation process.

11. A fabrication method for a gate oxide layer, the method comprising:
providing a substrate, the substrate comprising a trench and a mask layer that partially covers an active region surrounded by the trench;
forming an insulation layer on the substrate to fill the trench, wherein the insulation layer exposes the mask layer;
removing a portion of the mask layer to form a spacer on a sidewall of the insulation layer and expose a surface of the substrate at the active region;
implanting dopants to the exposed substrate surface at the active region;
removing the spacer;
removing a portion of the insulation layer to expose the substrate at a top edge corner of the trench; and
performing an oxidation process to form a gate oxide layer on the substrate.

12. The method of claim 11, wherein the step of implanting the dopants to the exposed substrate surface at the active region comprises performing an ion implantation process.

13. The method of claim 12, wherein the dopants comprise nitrogen ions.

14. The method of claim 13, wherein a dosage of the dopant is controlled to be within a range where an oxidation rate of the substrate at the active region is substantially equal to an oxidation rate of the substrate near the top edge corner of the trench.

15. The method of claim 13, wherein a concentration of the dopants is about 5×10¹¹/cm² to about 1×10¹⁵/cm².

16. The method of claim 11, wherein the step of forming the insulation layer further comprises:
forming an insulation material layer on the substrate; and
removing a portion of the insulation material layer until the mask layer is exposed to form the insulation layer that fills the trench.

17. The method of claim 16, wherein the insulation material layer is formed by a chemical vapor deposition process.

18. The method of claim 17, wherein the chemical vapor deposition process uses reaction gas sources that comprises tetra ethyl ortho silicate (TEOS)/ozone (O₃).

19. The method of claim 11, wherein the step of forming the gate oxide layer comprises performing a thermal oxidation process.

20. The method of claim 11, wherein a material consistuting the mask layer comprises silicon nitride.
